(19) United States
(12) Patent Application Publication
(10) Pub. No.: US 2026/0357464 A1
(43) Pub. Date: Nov. 12, 2026

(54) A COMPOSITION FOR COPPER NANOTWIN ELECTRODEPOSITION

(71) Applicant: BASF SE, Ludwigshafen am Rhein (DE)

(72) Inventors: Marco ARNOLD, Ludwigshafen am Rhein (DE); Alexander FLUEGEL, Ludwigshafen am Rhein (DE); Chih Hao HSIA, Taoyuan City (TW); Nadine ENGELHARDT, Ludwigshafen am Rhein (DE); Shu Ya CHANG, Taoyuan City (TW); Chun Ta CHEN, Xinzhuang District (TW)

(21) Appl. No.: 19/134,940

(22) PCT Filed: Dec. 14, 2023
(86) PCT No.: PCT/EP2023/085758

§ 371 Date: Jun. 2, 2025

(30) Foreign Application Priority Data
Dec. 19, 2022 (EP) 22214501.3

(51) Int. Cl. C25D 3/38; C25D 5/02; C25D 7/12

(52) U.S. Cl. CPC C25D 3/38; C25D 5/02; C25D 7/12

(57) ABSTRACT

Disclosed herein is a composition for electrodepositing nanotwinned copper, the composition including
(a) copper ions;
(b) a gelatin that has a bloom number of from 30 to 150;
(c) halide ions; and
(d) an inorganic or organic acid.

### BACKGROUND OF THE INVENTION

The invention relates to a composition for electrodepositing nanotwinned copper comprising a gelatine type additive, its use, and a process for nanotwinned copper electrodeposition.

Copper lines are formed by electroplating the metal into very thin, high-aspect-ratio trenches and vias in a methodology commonly referred to as “damascene” processing (pre-passivation metallization).

With the advancement of microelectronics, there is a continual need to create smaller and denser interconnect features. One method towards this goal is the removal of solder between two separate substrates that connect copper vias, pads, bumps, or pillars, which can be accomplished, for example, by process called Cu—Cu hybrid bonding.

Due to the combination of excellent mechanical properties, good conductivity, and unique structure, nanotwinned copper has drawn attention for use in microelectronics. Nanotwinned copper (nt-Cu) exhibits excellent mechanical and electrical properties and may be used in a wide variety of applications in wafer-level packaging and advanced packaging designs. Nanotwinned copper represents ultrafine-grain copper whose grains contain a high density of layered nanoscopic twins divided by coherent twin boundaries.

Nanotwinned copper can be achieved in several ways, including, for example, sputtering and electrolytic deposition. Direct current electrolytic plating is very compatible with industrial mass production. Twinning may occur in a material where two parts of a crystal structure are symmetrically related to one another. In a face-centered cubic (FCC) crystal structure, of which copper is included, coherent twin boundaries may be formed as (111) mirror planes from which the typical stacking sequence of (111) planes is reversed. In other words, adjacent grains are mirrored across coherent twin boundaries in a layered (111)-structure. Twins grow in a layer-by-layer manner extending along a lateral (111) crystal plane where a twin thickness is on the order of nanometers, hence the name “nanotwins”.

Compared to copper having conventional grain boundaries, nanotwinned copper possesses strong mechanical properties, including high strength and high tensile ductility. Nanotwinned copper also demonstrates high electrical conductivity, which may be attributable to the twin boundary, causing electron scattering that is less significant compared to a grain boundary. Furthermore, nanotwinned copper exhibits high thermal stability, which may be attributable to the twin boundary having excess energy on the order of magnitude lower than that of a grain boundary. In addition, nanotwinned copper enables high copper atom diffusivity, which is useful for copper-to-copper direct bonding. Nanotwinned copper also shows high resistance to electromigration, which may be a result of twin boundaries slowing down electromigration-induced atomic diffusion. Nanotwinned copper demonstrates a strong resistance to seed etch that may be important in fine-line redistribution layer applications. Nanotwinned copper also shows low impurity incorporation, which results in fewer Kirkendall voids as a result of soldered reactions with the nanotwinned copper. In some implementations, nanotwinned copper enables direct copper-copper bonding. Such copper-copper bonding may occur at low temperatures, moderate pressures, and lower bonding forces/times. Typically, the deposition of copper structures results in rough surfaces. In some implementations, prior to copper-copper bonding, electrodeposition of nanotwinned copper may be followed by an electropolishing process to achieve smooth surfaces. With the smooth surfaces, the nanotwinned copper structure may be used in copper-copper bonding with shorter bonding times, lower temperatures, and fewer voids.

WO2020/092244 and US 2013/0270121 A1 describe a copper structure having a high density of nanotwinned copper deposited on a substrate. It does not describe the particular electrolytic copper plating bath but instead describes electroplating conditions like pulse current, low temperatures, and the like.

U.S. Pat. No. 10,566,314 describes how the optimal copper grain structure for Cu—Cu metal to metal bonding is columnar grain microstructure. The copper grain microstructure plated by the disclosed suppressor-only system produces a columnar grain structure as a result of plating nanotwinned copper.

US 2013/0122326 A1 discloses electrodeposited nano-twins copper layer and a method of fabricating the same. At least 50% in volume of the electrodeposited nano-twins copper layer comprises plural grains adjacent to each other, wherein the said grains are made of stacked twins, the angle of the stacking directions of the nano-twins between one grain and the neighboring grain is between 0 to 20 degrees. A plating solution comprises copper sulfate, chloride anion and methyl sulfonate, and other surfactant or lattice modification agent (such as BASF Lugalvan) can be added.

WO 2022/47480 A1 discloses an electroplating solution used to deposit copper having a high density of nanotwinned colunmar copper grains, the solution comprising a copper salt, a source of halide ions, and a linear or branched polyhydroxyl, e.g. a reaction product between 2,3-epoxy-1-propanol and aminic alcohol or ammonium alcohol.

Unpublished European patent application No. 22183676.0 discloses a new use of a polyaminoamide comprising a group of formula [B-A-B′—Z]ₙ[Y—Z]ₘ in a composition for electrodepositing nanotwinned copper.

CN 102400188 B discloses a method for preparing the <111> structure nano twin crystal Cu block material. The plating composition comprises 150-200 g/l CuSO₄, 2.5-15 ml/l of a 0.2-0.5 wt % gelatin solution and 0.2-1.0 ml/l of a 5-25 wt % NaCl solution. The properties of the gelatin are not further specified. A current density of 1-4 ASD with a direct current is used.

CN 110 724 981 B, discloses a method of depositing nanotwinned copper. The plating composition comprises a wetting agent and a surfactant, the wetting agent being 30-60 ppm polyethylene glycol or less than or equal to 50 ppm polyethyleneimine and the surfactant is 30-60 ppm gelatin. The properties of the gelatin are not further specified.

CN 110 760 903 A discloses a method of depositing nanotwinned copper. The electroplating composition comprises 120-200 g/l copper sulfate, 35-75 ml/l sulfuric acid, 30-100 ppm sodium chloride, 60-100 ppm gelatin, 10-000 ppm wetting agent (polyethylene glycol or polyethylene-imine), and water.

CN 114 875 461 A discloses a nano-twin copper plating solution comprising copper ions, sulfuric acid, chloride ions, a nano-twin copper plating aid, an inhibitor, and water. The nano twin copper plating assistant comprises nickel ions and preferably the inhibitor comprises gelatin. Preferably, the gelatin has a congealing value of 10 to 300 bloom, such as 10 bloom, 20 bloom, 30 bloom, 50 bloom, 70 bloom, 80 bloom, 100 bloom, 125 bloom, 150 bloom, 180 bloom, 200 bloom, 225 bloom, 240 bloom, 260 bloom, 300 bloom, and the like.

CN 112 779 572 B discloses a method for preparing a nano twin copper thin film material comprising a plating solution that comprises copper ions, sulfuric acid, chloride ions, an accelerator and water. Preferably, the accelerating agent comprises gelatin, and the gelatin has a condensation value of 10 to 300 bloom, such as 10 bloom, 20 bloom, 30 bloom, 50 bloom, 70 bloom, 80 bloom, 100 bloom, 125 bloom, 150 bloom, 180 bloom, 200 bloom, 225 bloom, 240 bloom, 260 bloom or 300 bloom, etc., Preferably, the plating solution contains a monobasic fatty acid salts adjuvant to assist desorption of the accelerating agent to expose other crystal faces to grow into isometric crystals.

CN 110 724 981 B discloses a composition for preparing a <111> structure nano twin crystal Cu block material that comprises CuSO₄, gelatin, and NaCl at a pH of 0.5-1.5. No characteristics, particularly no bloom values of molecular weights of the gelatin are mentioned.

However, there remains a need in the art for an improved electrolytic copper composition for producing nanotwinned copper deposits. In addition, there remains a need in the art for an improved electrolytic copper composition that can deposit nanotwinned copper in (111) orientation and with a high amount of nanotwinning and a narrow transition layer.

It is an object of the present invention to provide an acidic copper electroplating composition that provides copper deposits with nanotwinned copper in (111) orientation and with a high amount of nanotwinning.

### SUMMARY OF THE INVENTION

Surprisingly, it has now been found, that the use of a specific gelatine is capable of forming nanotwinned copper, particularly nanotwinned copper in (111) orientation, with a high amount of nanotwinning and a narrow transition layer.

Therefore, the present invention provides a composition for electrodepositing nanotwinned copper, the composition comprising
(a) copper ions;
(b) a gelatin that has a bloom number of 30 to 150;
(c) halide ions;
(d) an inorganic or organic acid.

The nanotwin promotors according to the present invention are particularly useful for depositing nanotwinned copper in (111) orientation with a high amount of nanotwinning and a thinner transition layer. The compositions according to the invention show an increase number and quality of nonotwinning compared to those comprising gelatin outside the specified bloom range. Furthermore, by using the allow the filling recessed features on the micrometer scale without substantially forming defects, such as but not limited to voids. The nanotwin promotors provide a copper electroplating bath that provides a uniform and planar copper deposit, in particular in recessed features.

Furthermore, the nanotwin promotors lead to reduced impurities, such as but not limited to organics, chloride, sulfur, nitrogen, or other elements. Especially, when solder is directly plated on copper higher organic impurity levels lead to pronounced Kirkendall voiding. These voids lower the reliability of the solder stack and is therefore less preferred. The additives described herein additionally facilitate high plating rates and allows plating at elevated temperature.

The invention further relates to the use of a composition according to anyone of the preceding claims for depositing nanotwinned copper on a substrate, particularly a semiconductor substrate.

The invention further relates to a process for electrodepositing copper on a substrate comprising a recessed feature comprising a conductive feature bottom and a dielectric feature side wall, the process comprising:
a) contacting a composition according to anyone of claims 1 to 12 with the substrate, and
b) applying a current to the substrate for a time sufficient to deposit nanotwinned copper on the substrate.

### BRIEF DESCRIPTION OF THE FIGURES

FIG. 1 shows an overview FIB-SAM picture of a copper layer electrodeposited using a composition according to the example with gelatin 1;

FIG. 2 shows an overview FIB-SAM picture of a copper layer electrodeposited using a composition according to the example with gelatin 2;

FIG. 3 shows an overview FIB-SAM picture of a copper layer electrodeposited using a composition according to the example with gelatin C3;

FIG. 4 shows an overview FIB-SAM picture of a copper layer electrodeposited using a composition according to the example with gelatin C4;

FIG. 5 shows an overview FIB-SAM picture of a copper layer electrodeposited using a composition according to the example with gelatin C5;

### DETAILED DESCRIPTION OF THE INVENTION

It has been surprisingly found, that gelatin, particularly mammalian gelatin, having a Bloom value of from 30 to 150 may advantageously be used as nanotwin promotors in the copper electrodeposition, i.e. it helps to deposit copper having a columnar (111) orientation. Such gelatine lead to a high amount of nanotwins in the deposited copper layers. This gelatin is also referred to herein as “nanotwin promotor”.

As used herein, “accelerator” refers to an organic additive that increases the plating rate of the electroplating bath. The terms “accelerator” and “accelerating agent” are used interchangeably throughout this specification. In literature, sometimes the accelerator component is also named “brightener” or “brightening agent”. “Suppressing agent” or “suppressor” refers to an organic compound that decreases the plating rate of the electroplating bath and ensures that the recessed features are voidless filled from the bottom to the top (so called “bottom-up filling”). The terms “suppressors” and “suppressing agents” are used interchangeably throughout this specification. “Leveler” refers to an organic compound that is capable of providing a substantially planar metal deposit over areas with a higher or lower number of recessed features, or different areas across a wafer or die. The terms “leveler”, “leveling agent” and “leveling additive” are used interchangeably throughout this specification.

“Aperture size” according to the present invention means the smallest diameter or free distance of a recessed feature before plating. The terms “width”, “diameter”, “aperture” and “opening” are used herein, depending on the geometry of the feature (trench, via, etc.) synonymously. As used herein, “aspect ratio” means the ratio of the depth to the aperture size of the recessed feature.

As used herein, “chemical bond” means that the respective moiety is not present but that the adjacent moieties are bridged so as to form a direct chemical bond between these adjacent moieties. By way of example, if in a molecule A-B-C the moiety B is a chemical bond then the adjacent moieties A and C together form a group A-C.

The term “Cₓ” means that the respective group comprises x numbers of C atoms. The term “Cₓ to C_{y} alkyl” means alkyl with a number x to y of carbon atoms and, unless explicitly specified, includes unsubstituted linear, branched and cyclic alkyl. As used herein, “alkanediyl” refers to a diradical of linear, branched or cyclic alkanes or a combination thereof.

As used herein, “aromatic rings” cover aryl and heteroaryl groups.

As used herein, a “high amount of nanotwinning” or “high amount of nanotwins” refers to copper structures having greater than about 80% nanotwinning, and even greater than about 90% nanotwinning as observed using suitable microscopy techniques.

### Nanotwin Promotor

The electroplating composition comprises at least one gelatin nanotwin promotor. To receive a high amount of nanotwinning and a narrow transition layer it was found that the gelatin needs to have a low bloom number below about 150. It must also have a gelling property, i.e. a bloom number of at least about 30. The gelatin according to the invention is also referred to herein as “nanotwin promotor”.

Preferably the gelatine may have a bloom number of from about 40 to about 140, more preferably of from about 50 to about 130, even more preferably from about 60 to about 135, most preferably of from about 75 to about 125. Mammalian, preferably bovine or porcine based gelatin, most preferably gelatine from bovine or porcine skin, shows bloom number in this range. In contrast, fish-based gelatin has generally lower concentration of imino acids and shows insufficient gelling strength.

Generally, the mass average molecular mass M_{w} of the nanowin promotor may be from about 10 000 to about 60 000 g/mol, preferably from about 12 000 to about 50 000 g/mol, more preferably from about 13 000 to about 40 000 g/mol, even more preferably from about 15 000 to about 30 000 g/mol, most preferably from about 20 000 to about 30 000 g/mol.

In a preferred embodiment the free carboxyl groups in the gelatin are of from 60 to 130 mmol/100 g, In one embodiment the free carboxyl groups are of from about 90 to about 130 mmol/100 g. In another embodiment the free carboxyl groups are of from about 70 to about 100 mmol/100 g.

In general, the total amount of nanotwin promotors in the electroplating bath is from 0.05 ppm to 10000 ppm based on the total weight of the plating bath. The nanotwin promotors are typically used in a total amount of from about 0.1 ppm to about 1000 ppm and more typically from 2 to 250 ppm based on the total weight of the plating bath, although greater or lesser amounts may be used. Most preferably the nanotwin promotors are used in a total amount of from about 5 ppm to about 100 ppm, particularly from about 7.5 ppm to about 50 ppm based on the total weight of the plating bath.

### Other Additives

A large variety of further additives may typically be used in the bath to provide desired surface finishes for the Cu plated metal. Usually more than one additive is used with each additive forming a desired function. Advantageously, the electroplating baths may contain one or more of accelerators, suppressors, levelers, sources of halide ions, grain refiners and mixtures thereof. Most preferably the electroplating bath contains both, an accelerator, and a suppressing agent in addition to the nanotwin promotor according to the present invention. Other additives may also be suitably used in the present electroplating baths.

### Accelerators

In general, any accelerators may be used in the plating baths according to the present invention. As used herein, “accelerator” refers to an organic additive that increases the plating rate of the electroplating bath. The terms “accelerator” and “accelerating agent” are used interchangeably throughout this specification. In literature, sometimes the accelerator component is also named “brightener”, “brightening agent”, or “depolarizer”. Accelerators useful in the present invention include, but are not limited to, compounds comprising one or more sulphur atom and a sulfonic/phosphonic acid or their salts. In one embodiment the composition further comprises at least one accelerating agent. In another embodiment the composition is free of any sulfur-containing accelerators.

If present, preferred accelerators have the general structure MO₃Y^{A}—X^{A1}—(S)_{d}R^{A2}, with:
M is a hydrogen or an alkali metal, preferably Na or K;
Y^{A} is P or S, preferably S;
d is an integer from 1 to 6, preferably 2;
X^{A1} is selected from a C₁-C₈ alkanediyl or heteroalkanediyl group, a divalent aryl group or a divalent heteroaromatic group. Heteroalkyl groups will have one or more heteroatom (N, S, O) and 1-12 carbons. Carbocyclic aryl groups are typical aryl groups, such as phenyl or naphthyl. Heteroaromatic groups are also suitable aryl groups and contain one or more N, O or S atom and 1-3 separate or fused rings.
R^{A2} is selected from H or (—S—X^{A1′}Y^{A}O₃M), wherein X^{A1′} is independently selected from group X^{A1}.

More specifically, useful accelerators include those of the following formulae:

MO₃S—X^{A1}—SH

MO₃S—X^{A1}—S—S—X^{A1′}—SO₃M

MO₃S—Ar—S—S—Ar—SO₃M
wherein X^{A1} is as defined above and Ar is aryl.

Particularly preferred accelerators are:
SPS: bis-(3-sulfopropyl)-disulfide
MPS: 3-mercapto-1-propansulfonic acid.

Both are usually applied in form of their salts, particularly their sodium salts.

Other examples of accelerators, used alone or in mixture, include, but are not limited to: MES (2-Mercaptoethanesulfonic acid, sodium salt); DPS (N,N-dimethyldithiocarbamic acid (3-sulfopropylester), sodium salt); UPS (3-[(amino-iminomethyl)-thio]-1-propylsulfonic acid); ZPS (3-(2-benzthiazolylthio)-1-propanesulfonic acid, sodium salt); 3-mercapto-propylsulfonicacid-(3-sulfopropyl) ester; methyl-(w-sulphopropyl)-disulfide, disodium salt; methyl-(w-sulphopropyl)-trisulfide, disodium salt.

If used, such accelerators are typically used in an amount of about 0.1 ppm to about 3000 ppm, based on the total weight of the plating bath. Particularly suitable amounts of accelerator useful in the present invention are 1 to 500 ppm, and more particularly 2 to 100 ppm.

### Suppressing Agents

Suppressing agents may be used in combination with the additives according to the present inventions. As used herein, “suppressing agents” are additives which increase the overpotential during electrodeposition. The terms “surfactant” and “suppressing agent” are synonymously used since the suppressing agents described herein are also surface-active substances. Usually suppressing agents are polyalkylene oxides comprising oxy (C₂ to C₄)alkylene homo- or coplymers, obtainable by polyoxyalkylation of an alcohol or amine starter. In one embodiment the composition further comprises at least one suppressing agent. In another embodiment the composition is free of any polyol suppressing agent, particularly free of any polyalkylene glycol and polyoxyalkylene-type suppressing agent, most particularly free of any polyoxyalkylene-type suppressing agent.

If present, particularly useful suppressing agents are:

(a) Suppressing agents obtainable by reacting an amine compound comprising at least three active amino functional groups with a mixture of ethylene oxide and at least one compound selected from C₃ and C₄ alkylene oxides as described in WO 2010/115796.

Preferably the amine compound is selected from diethylene triamine, 3-(2-aminoethyl)aminopropylamine, 3,3′-iminodi (propylamine), N,N-bis(3-aminopropyl)methylamine, bis(3-dimethylaminopropyl)amine, triethylenetetraamine and N,N′-bis(3-aminopropyl)ethylenediamine.

(b) Suppressing agents obtainable by reacting an amine compound comprising active amino functional groups with a mixture of ethylene oxide and at least one compound selected from C₃ and C₄ alkylene oxides, said suppressing agent having a molecular weight M_{w} of 6000 g/mol or more, forming an ethylene C₃ and/or C₄ alkylene random copolymer as described in WO 2010/115756.

(c) Suppressing agent obtainable by reacting an amine compound comprising at least three active amino functional groups with ethylene oxide and at least one compound selected from C₃ and C₄ alkylene oxides from a mixture or in sequence, said suppressing agent having a molecular weight M_{w} of 6000 g/mol or more as described in WO 2010/115757.

Preferably the amine compound is selected from ethylene diamine, 1,3-diaminopropane, 1,4-diaminobutane, 1,5-diaminopentane, 1,6-diaminohexane, neopentanediamine, isophoronediamine, 4,9-dioxadecane-1,12-diamine, 4,7,10-trioxyatridecane-1,13-diamine, triethylene glycol diamine, diethylene triamine, (3-(2-aminoethyl)aminopropylamine, 3,3′-iminodi (propylamine), N, N-bis(3-aminopropyl)methylamine, bis(3-dimethylaminopropyl)amine, triethylenetetraamine and N,N′-bis(3-aminopropyl)ethylenediamine.

(d) Suppressing agent selected from compounds of formula S1

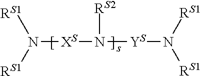

wherein the R^{S1} radicals are each independently selected from a copolymer of ethylene oxide and at least one further C₃ to C₄ alkylene oxide, said copolymer being a random copolymer, the R^{S2} radicals are each independently selected from R^{S1} or alkyl, X^{S} and Y^{S} are spacer groups independently, and X^{S} for each repeating unit s independently, selected from C₂ to C₆ alkandiyl and Z^{S}—(O—Z^{S}), wherein the Z^{S} radicals are each independently selected from C₂ to C₆ alkandiyl, s is an integer equal to or greater than 0, and t is an integer equal to or greater than 1, as described in WO 2010/115717.

Preferably spacer groups X^{S} and Y^{S} are independently, and X^{S} for each repeating unit independently, selected from C₂ to C₄ alkylene. Most preferably X^{S} and Y^{S} are independently, and X^{S} for each repeating unit s independently, selected from ethylene (—C₂H₄—) or propylene (—C₃H₆—).

Preferably Z^{S} is selected from C₂ to C₄ alkylene, most preferably from ethylene or propylene.

Preferably s is an integer from 1 to 10, more preferably from 1 to 5, most preferably from 1 to 3. Preferably t is an integer from 1 to 10, more preferably from 1 to 5, most preferably from 1 to 3.

In another preferred embodiment the C₃ to C₄ alkylene oxide is selected from propylene oxide (PO). In this case EO/PO copolymer side chains are generated starting from the active amino functional groups

The content of ethylene oxide in the copolymer of ethylene oxide and the further C₃ to C₄ alkylene oxide can generally be from about 5% by weight to about 95% by weight, preferably from about 30% by weight to about 70% by weight, particularly preferably between about 35% by weight to about 65% by weight.

The compounds of formula (S1) are prepared by reacting an amine compound with one or more alkylene oxides. Preferably the amine compound is selected from ethylene diamine, 1,3-diaminopropane, 1,4-diaminobutane, 1,5-diaminopentane, 1,6-diaminohexane, neopentanediamine, isophoronediamine, 4,9-dioxadecane-1,12-diamine, 4,7,10-trioxatridecane-1,13-diamine, triethylene glycol diamine, diethylene triamine, (3-(2-aminoethyl)amino)propylamine, 3,3′-iminodi(propylamine), N,N-bis(3-aminopropyl)methylamine, bis(3-dimethylaminopropyl)amine, triethylenetetraamine and N,N′-bis(3-aminopropyl)ethylene-diamine.

The molecular weight M_{w} of the suppressing agent of formula S1 may be between about 500 g/mol to about 30000 g/mol. Preferably the molecular weight M_{w} should be about 6000 g/mol or more, preferably from about 6000 g/mol to about 20000 g/mol, more preferably from about 7000 g/mol to about 19000 g/mol, and most preferably from about 9000 g/mol to about 18000 g/mol. Preferred total amounts of alkylene oxide units in the suppressing agent may be from about 120 to about 360, preferably from about 140 to about 340, most preferably from about 180 to about 300.

Typical total amounts of alkylene oxide units in the suppressing agent may be about 110 ethylene oxide units (EO) and 10 propylene oxide units (PO), about 100 EO and 20 PO, about 90 EO and 30 PO, about 80 EO and 40 PO, about 70 EO and 50 PO, about 60 EO and 60 PO, about 50 EO and 70 PO, about 40 EO and 80 PO, about 30 EO and 90 PO, about 100 EO and 10 butylene oxide (BO) units, about 90 EO and 20 BO, about 80 EO and 30 BO, about 70 EO and 40 BO, about 60 EO and 50 BO or about 40 EO and 60 BO to about 330 EO and 30 PO units, about 300 EO and 60 PO, about 270 EO and 90 PO, about 240 EO and 120 PO, about 210 EO and 150 PO, about 180 EO and 180 PO, about 150 EO and 210 PO, about 120 EO and 240 PO, about 90 EO and 270 PO, about 300 EO and 30 BO units, about 270 EO and 60 BO, about 240 EO and 90 BO, about 210 EO and 120 BO, about 180 EO and 150 BO, or about 120 EO and 180 BO.

(e) Suppressing agent obtainable by reacting a polyhydric alcohol condensate compound derived from at least one polyalcohol of formula (S2) X^{S}(OH)ᵤ by condensation with at least one alkylene oxide to form a polyhydric alcohol condensate comprising polyoxyalkylene side chains, wherein u is an integer from 3 to 6 and X^{S} is an u-valent linear or branched aliphatic or cycloaliphatic radical having from 3 to 10 carbon atoms, which may be substituted or unsubstituted, as described in WO 2011/012462.

Preferred polyalcohol condensates are selected from compounds of formulae

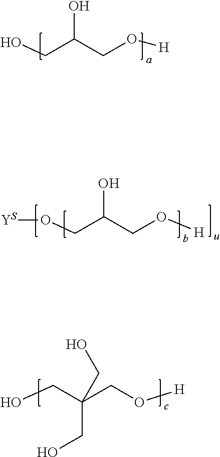

wherein Y^{S} is an u-valent linear or branched aliphatic or cycloaliphatic radical having from 1 to 10 carbon atoms, which may be substituted or unsubstituted, a is an integer from 2 to 50, b may be the same or different for each polymer arm u and is an integer from 1 to 30, c is an integer from 2 to 3, and u is an integer from 1 to 6. Most preferred Polyalcohols are glycerol condensates and/or pentaerythritol condensates.

(f) Suppressing agent obtainable by reacting a polyhydric alcohol comprising at least 5 hydroxyl functional groups with at least one alkylene oxide to form a polyhydric alcohol comprising polyoxyalkylene side chains as described in WO 2011/012475. Preferred polyalcohols are linear or cyclic monosaccharide alcohols represented by formula (S3a) or (S3b)

HOCH₂—(CHOH)ᵥ—CH₂OH (S3a)

(CHOH)_{w} (S3b)

wherein v is an integer from 3 to 8 and w is an integer from 5 to 10. Most preferred monosaccharide alcohols are sorbitol, mannitol, xylitol, ribitol and inositol. Further preferred polyalcohols are monosaccharides of formula (S4a) or (S4b)

CHO—(CHOH)ₓ—CH₂OH (S4a)

CH₂OH—(CHOH_{y}—CO—(CHOH)_{z}—CH₂OH (S4b)

wherein x is an integer of 4 to 5, and y, z are integers and y+z is 3 or 4. Most preferred monosaccharide alcohols are selected from the aldoses allose, altrose, galactose, glucose, gulose, idose, mannose, talose, glucoheptose, mannoheptose or the ketoses fructose, psicose, sorbose, tagatose, mannoheptulose, sedoheptulose, taloheptulose, alloheptulose.

(g) amine-based polyoxyalkylene suppressing agents based on cyclic amines show extraordinary superfilling properties, as described in WO 2018/073011.

(h) polyamine-based or polyhydric alcohol-based suppressing agents which are modified by reaction with a compound, such as but not limited to glycidole or glycerol carbonate, that introduce a branching group into the suppressing agent before they are reacted with alkylene oxides show extraordinary superfilling properties, as described in WO 2018/114985.

When suppressors are used, they are typically present in an amount in the range of from about 1 to about 10,000 ppm based on the weight of the bath, and preferably from about 5 to about 10,000 ppm. In one embodiment the composition is free of any suppressing agents described in this section.

### Leveling Agents

Additional leveling agents may be used in the copper electroplating baths according to the present invention.

Suitable leveling agents include, but are not limited to, one or more of other polyethylene imines and derivatives thereof, quaternized polyethylene imine, polyglycine, poly(allylamine), polyaniline, polyurea, polyacrylamide, poly(melamine-co-formaldehyde), reaction products of amines with epichlorohydrin, reaction products of an amine, epichlorohydrin, and polyalkylene oxide, reaction products of an amine with a polyepoxide, polyvinylpyridine, polyvinylimidazole as described e.g. in WO 2011/151785 A1, polyvinylpyrrolidone, polyaminoamides as described e.g. in WO 2011/064154 A2 and WO 2014/072885 A2, or copolymers thereof, nigrosines, pentamethyl-para-rosaniline hydrohalide, hexamethyl-pararosaniline hydrohalide, di- or trialkanolamines and their derivatives as described in WO 2010/069810, biguanides as described in WO 2012/085811 A1, or a compound containing a functional group of the formula N—R—S, where R is a substituted alkyl, unsubstituted alkyl, substituted aryl or unsubstituted aryl. Typically, the alkyl groups are C₁-C₆ alkyl and preferably C₁-C₄ alkyl. In general, the aryl groups include C₆-C₂₀ aryl, preferably C₆-C₁₀ aryl. It is preferred that the aryl group is phenyl or naphthyl. The compounds containing a functional group of the formula N—R—S are generally known, are generally commercially available and may be used without further purification.

In such compounds containing the N—R—S functional group, the sulfur (“S”) and/or the nitrogen (“N”) may be attached to such compounds with single or double bonds. When the sulfur is attached to such compounds with a single bond, the sulfur will have another substituent group, such as but not limited to hydrogen, C₁-C₁₂ alkyl, C₂-C₁₂ alkenyl, C₆-C₂₀ aryl, C₁-C₁₂ alkylthio, C₂-C₁₂ alkenylthio, C₆-C₂₀ arylthio and the like. Likewise, the nitrogen will have one or more substituent groups, such as but not limited to hydrogen, C₁-C₁₂ alkyl, C₂-C₁₂ alkenyl, C₇-C₁₀ aryl, and the like. The N—R—S functional group may be acyclic or cyclic. Compounds containing cyclic N—R—S functional groups include those having either the nitrogen or the sulfur or both the nitrogen and the sulfur within the ring system.

More details and alternatives are described in WO 2018/219848, WO 2016/020216, and WO 2010/069810, respectively, which are incorporated herein by reference.

In one embodiment the composition further comprises at least one leveling agent as disclosed above. In another embodiment the composition is free of any leveling agent described in this section.

If used, in general, the total amount of leveling agents in the electroplating bath is from 0.5 ppm to 10000 ppm based on the total weight of the plating bath. The leveling agents according to the present invention are typically used in a total amount of from about 100 ppm to about 10000 ppm based on the total weight of the plating bath, although greater or lesser amounts may be used.

### Electrolyte

The electroplating composition according to the present invention comprises and electrolyte comprising copper ions and an acid.

### Copper Ions

The source of copper ions may be any compound capable of releasing metal ions to be deposited in the electroplating bath in sufficient amount, i.e. is at least partially soluble in the electroplating bath. It is preferred that the metal ion source is soluble in the plating bath. Suitable metal ion sources are metal salts and include, but are not limited to, sulfates, halides, acetates, nitrates, fluoroborates, alkylsulfonates, arylsulfonates, sulfamates, metal gluconates and the like.

The copper ion source may be used in the present invention in any amount that provides sufficient metal ions for electroplating on a substrate. Copper is typically present in an amount in the range of from about 1 to about 300 g/l of plating solution, preferably from about 20 to about 100 g/l, most preferably from about 40 to about 70 g/l.

In a preferred embodiment the plating solution is essentially free of tin and/or nickel ions, that is, it contains below 1% by weight tin and/or nickel ions, more preferably below 0.1% by weight tin and/or nickel ions, and yet more preferably below 0.01% by weight tin and/or nickel ions, and still more preferably is free of tin and/or nickel ions. In another preferred embodiment the plating solution is essentially free of any group 1 or 2 metal ions, that is, it contains below 1% by weight of such metal ions, more preferably below 0.1% by weight of such metal ions, and yet more preferably below 0.01% by weight of such alkaline or alkaline earth metal ions, and still more preferably is free of any alkaline or alkaline earth metal ions. In yet another preferred embodiment the plating solution is essentially free of any alloying metal ions, that is, they contain below 1% by weight alloying metal ions, more preferably below 0.1% by weight alloying metal, even more preferably below 0.01% by weight alloying metal ions, and still more preferably are free of alloying metal ions. Most preferably the metal ions consist of copper ions, i.e., the composition is free of any other metal ions besides copper ions.

### Acid

The plating baths of the invention are preferably acidic, that is, they have a pH below 7. Typically, the pH of the copper electroplating composition is below 4, preferably below 3, most preferably below 2. The pH mainly depends on the concentration of the acid present in the composition.

Suitable acids include inorganic acids and organic acids, such as, but not limited to, sulfuric acid, acetic acid, fluoroboric acid, alkylsulfonic acids such as methanesulfonic acid, ethanesulfonic acid, propanesulfonic acid and trifluoromethane sulfonic acid, arylsulfonic acids such as phenyl sulfonic acid and toluenesulfonic acid, sulfamic acid, hydrochloric acid, and phosphoric acid. Sulfuric acid and methanesulfonic acid are preferred.

The acids are typically present in an amount in the range of from about 1 to about 300 g/l, preferably from about 5 to about 200 g/l, most preferably from about 7.5 to about 50 g/l.

Such electrolytes may optionally (and preferably) contain a source of halide ions, such as chloride ions as in copper chloride or hydrochloric acid. A wide range of halide ion concentrations may be used in the present invention such as from about 0 to about 500 ppm. Preferably, the halide ion concentration is in the range of from about 10 to about 100 ppm based on the plating bath. It is preferred that the electrolyte is sulfuric acid or methanesulfonic acid, and preferably a mixture of sulfuric acid or methanesulfonic acid and a source of chloride ions. The acids and sources of halide ions useful in the present invention are generally commercially available and may be used without further purification.

### Electroplating Bath

The present electroplating compositions are suitable for depositing a copper-containing layer, which may preferably be a pure copper layer.

In general, besides the copper ions and at least one of the nanotwin promotors, the present copper electroplating compositions comprise an acidic electrolyte, halide ions, and optionally other additives like accelerators or suppressing agents.

Such baths are typically aqueous. In general, as used herein “aqueous” means that the present electroplating compositions comprises a solvent comprising at least 50% by weight of water. Preferably, “aqueous” means that the major part of the composition is water, more preferably 90% by weight of the solvent is water, most preferably the solvent consists or essentially consists of water. Any type of water may be used, such as distilled, deionized or tap. Furthermore, such baths are typically homogenous solutions, i.e., they are free of any particles.

It was found that the introduction of other organic electroplating compounds has a negative impact or may even disrupt the ability of the nanotwin promotors to produce nanotwinned copper. These prohibitive compounds include all organic additives that are usually present in a copper electroplating bath, particularly accelerators, suppressing agents, surfactants, and/or leveling agents. Thus, in a preferred embodiment, the electroplating composition is at least substantially free of any accelerator, suppressing agent, surfactant, and/or leveling agent. In another preferred composition the electroplating composition is at least substantially free of any sulfur containing compounds (typical accelerators) and polyol compounds, particularly polyalkylene oxide compounds (typical suppressors).

In one preferred embodiment, the copper electroplating composition of the present invention comprises, essentially consists of or consists of:
a) about 20 to about 60 g/l, preferably about 30 to about 50 g/l copper ions;
b) about 5 to about 70 g/l, preferably about 7.5 to about 40 g/l of an acid, particularly sulfuric acid;
c) about 20 to about 120 mg/l halide ions, preferably about 30 to about 70 mg/l halide ions particularly chloride ions;
d) about 2 to about 250 mg/l, preferably about 3 to about 50 mg/l, most preferably about 5 to about 30 mg/l of the nanotwin promotor as described herein, wherein the composition is free of any sulfur-containing accelerators or compounds and free of any polyol suppressing agents or compounds, particularly polyglycols and polyalkylene oxides.

As used herein, “substantially free of” means that the electroplating composition contains less than 10 ppm, more preferably less than about 5 ppm, and most preferably less than about 2 ppm of any compound that can function as an accelerator, suppressing agent, or leveling agent.

In another preferred embodiment, the electroplating composition essentially consists of or consists of
(a) copper ions;
(b) the nanotwin promotor as described herein;
(c) halide ions;
(d) inorganic or organic acid;
(d) optionally a sulfur containing accelerating agent; and
(e) optionally a polyalkylene oxide suppressing agent.

In another preferred embodiment, the electroplating composition essentially consists of or consists of
a) copper ions;
b) the nanotwin promotor as described herein
c) an acid, particularly sulfuric acid;
d) halide ions, particularly chloride ions.

In yet another preferred embodiment, the electroplating composition consists essentially of a copper electroplating composition capable of electrodepositing nanotwinned copper, the electroplating composition consisting essentially of or consisting of:
a) about 40 to about 60 g/l copper ions;
b) about 80 to about 140 g/l of an acid, particularly sulfuric acid;
c) about 30 to about 120 mg/l halide ions, particularly chloride ions;
d) about 300 to about 500 mg/l of the nanotwin promotor as described herein.

In yet another preferred embodiment, the electroplating composition consists essentially of a copper electroplating composition capable of electrodepositing nanotwinned copper, the electroplating composition consisting essentially of or consisting of:
a) about 20 to about 60 g/l, preferably about 30 to about 50 g/l copper ions;
b) about 5 to about 70 g/l, preferably about 7.5 to about 40 g/l of an acid, particularly sulfuric acid;
c) about 20 to about 120 mg/l halide ions, preferably about 30 to about 70 mg/l halide ions particularly chloride ions;
d) about 2 to about 250 mg/l, preferably about 5 to about 100 mg/l, most preferably about 5 to about 50 mg/l of the nanotwin promotor as described herein.

### Process

The compositions comprising the nanotwin promotors are particularly useful for electrodepositing nanotwinned copper, preferably in in (111) orientation, with a high amount of nanotwinning on a substrate, particularly a semiconductor substrate.

In general, when the present invention is used to deposit copper on a substrate the plating baths are agitated during use. Any suitable agitation method may be used with the present invention and such methods are well-known in the art. Suitable agitation methods include, but are not limited to, inert gas or air sparging, work piece agitation, impingement, and the like. Such methods are known to those skilled in the art. When the present invention is used to plate an integrated circuit substrate, such as a wafer, the wafer may be rotated such as from 1 to 150 RPM and the plating solution contacts the rotating wafer, such as by pumping or spraying. In the alternative, the wafer need not be rotated where the flow of the plating bath is sufficient to provide the desired metal deposit.

Plating equipments for plating semiconductor substrates are well known. Plating equipment comprises an electroplating tank which holds copper electrolyte, and which is made of a suitable material such as plastic or other material inert to the electrolytic plating solution. The tank may be cylindrical, especially for wafer plating. A cathode is horizontally disposed at the upper part of tank and may be any type of substrate such as a silicon wafer having openings.

These additives can be used with soluble and insoluble anodes in the presence or absence of a membrane or membranes separating the catholyte from the anolyte.

The cathode substrate and anode are electrically connected by wiring and, respectively, to a power supply. The cathode substrate for direct or pulse current has a net negative charge so that the metal ions in the solution are reduced at the cathode substrate forming plated metal on the cathode surface. An oxidation reaction takes place at the anode. The cathode and anode may be horizontally or vertically disposed in the tank.

The current density is generally in the range of from about 0.01 to about 50 ASD (ampere per square decimeter), preferably from about 0.5 to about 20 ASD, most preferably from about 1 to about 10 ASD. In addition, the electroplating solution is preferably agitated, and the electroplating solution is generally mixed at about 1 to about 2,500 rpm, more preferably about 10 to about 1,200 rpm, most preferably about 50 to about 400 rpm.

In general, when preparing copper bumps, a photoresist layer is applied to a semiconductor wafer, followed by standard photolithographic exposure and development techniques to form a patterned photoresist layer (or plating mask) having recessed features or vias therein. The dimensions of the dielectric plating mask (thickness of the plating mask and the size of the openings in the pattern) defines the size and location of the copper layer deposited over the I/O pad and UBM. The diameter of such deposits typically ranges of from 1 to 300 μm, preferably in the range from 2 to 100 μm. Usually, the recesses provided by the plating mask are not fully but only partly filled. After filling the openings in the plating mask with copper, the plating mask is removed, and then the copper bumps are usually subjected to reflow processing.

Generally, the substrate to be plated does not need to have a specific orientation to allow copper nanotwin deposition. However, it is preferred that the substrate to be plated comprises a copper seed layer with a dominan <111> orientation.

Typically, the plating baths of the present invention may be used at any temperature from 10 to 65 °C or higher. It is preferred that the temperature of the plating baths is from 10 to 35 °C and more preferably from 15 degrees to 30 °C.

All percent, ppm or comparable values refer to the weight with respect to the total weight of the respective composition except where otherwise indicated. All cited documents are incorporated herein by reference.

The following examples shall further illustrate the present invention without restricting the scope of this invention.

### Analytical Methods

Generally, the Bloom value (or number) is a measure for the strength of a gel. The test determines the weight in grams needed by a specified plunger (normally with a diameter of 0.5 inch) to depress the surface of the gel by 4 mm without breaking it at a specified temperature. The number of grams is called the Bloom number (or Bloom value). To perform the Bloom test on gelatin, a 6.67% gelatin solution is kept for 17 hours at 10 °C prior to being tested (Manufacturers Institute of America, Standard Methods for the Sampling and Testing of Gelatines, 1986).

The substrates were blanket wafer pieces comprising a Cu-seed layer with a dominant <111> orientation.

The presence of nanotwinned grain structures can be observed using any suitable microscopy technique, such as an electron microscopy technique. The amount of nanotwinned grain structure in the copper deposit is preferably greater than about 80%, more preferably greater than about 90% nanotwinned columnar copper grains, which can be estimated based on SEM cross-sections.

As set forth in the examples below, nanotwinned copper structures may be characterized by a plurality of (111)-oriented crystal copper grains containing a majority of nanotwins. In some implementations, the plurality of (111)-oriented crystal copper grains contain a high amount of nanotwins.

The crystal orientation of the crystal copper grains may be characterized using a suitable technique such as electron backscatter diffraction (EBSD) analysis. In some implementations, crystal orientation maps may be displayed in inverse pole figure (IPF) maps. In accordance with the present invention, it is preferably that the nanotwinned copper structures contain primarily (111)-oriented grains.

The electroplated copper was investigated by FIB-SEM.

### EXAMPLES

Several gelatins from different sources and with varying Bloom values were investigated. Gelatin from bovine skin (Nos. 1, C4), porcine skin (Nos. 2 and C3), and from fish skin (No. C5) were purchased from Sigma Aldrich. The information on the gelatine properties like bloom value and molar mass were taken from the information data sheets by Sigma Aldrich.

A copper electroplating bath containing 40 g/l Cu Ions, 10 g/l sulfuric acid and 50 ppm chloride was used for the studies. In addition, the bath contained 10 ppm of the respective nanotwin promotor.

The substrate was electrically connected prior plating. The copper layer was plated by using an RDE set-up. The electrolyte convection was realized by rotating the RDE. The rotating speed in the experiments was 100 RPM. Bath temperature was controlled and set to 25 °C. A current density of 1 ASD was applied for 68 min resulting in a copper layer of approximately 15 μm thickness.

The grain structure of the plated copper films was examined by FIB-SEM. The thickness of the transition layer was determined by measuring the average distance between the seed layer and the where the nanotwin layer growth started.

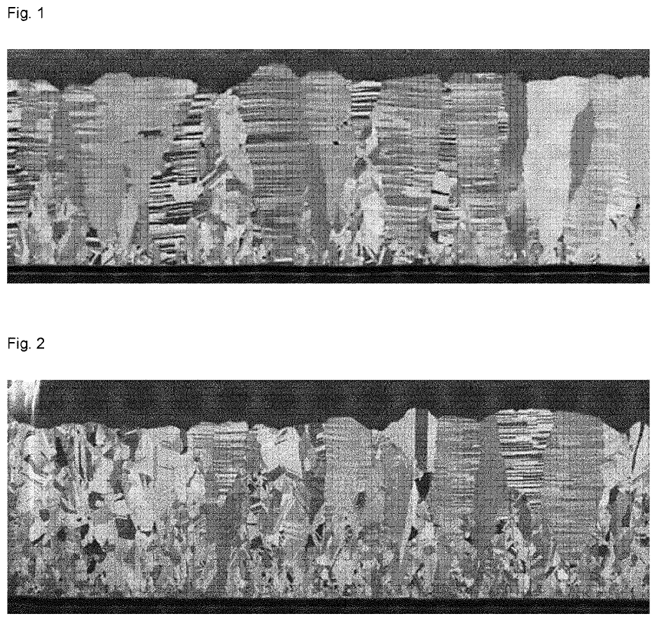

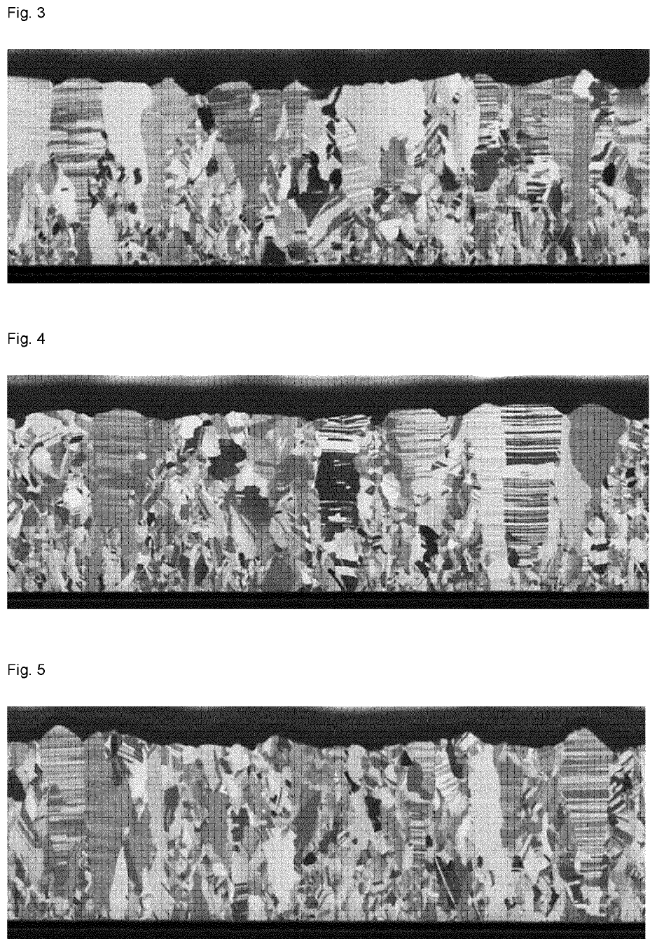

The results are depicted in Table 1 and shown in FIGS. 1 to 5 for nanotwin promotors 1 and to and comparative nanotwin promotors C3 to C5.

TABLE 1

| | | | | Free carboxyl | Transition |
|---|---|---|---|---|---|
| | | Bloom | Molar Mass | groups | layer |
| No. | Source | number | [g/mol] | [mmol/100 g ] | [μm] |
| 1 | bovine | 75 | 15.000-20.000 | 78-80 | 0.92 |
| 2 | porcine | 80-120 | 20.000-25.000 | 100-115 | 1.95 |
| C3 | porcine | 225 | 40.000-50.000 | 100-115 | 2.25 |
| C4 | bovine | 175 | 40.000-50.000 | 78-80 | 3.46 |
| C5 | fish | n/a | 60.000 | n/a | 3.04 |

The desired nanotwin formation can be easily seen from the horizontally layered structure in FIGS. 1 to 5. Nanotwin promotors 1 and 2 having a lower Bloom value of 75 or 80-120 lead to a higher amount of nanotwins in the deposited copper layer and a thinner transition layer compared with nanotwin promotors C3 and C4 having a higher Bloom value of 175 or 225, respectively. Nanotwin promotor C5 based on cold-water fish skin showed low gel and melting points. This gelatin type does not gel at 10 °C and also showed a bad nanotwin formation performance.

1. An aqueous composition for electrodepositing nanotwinned copper, the composition comprising
(a) copper ions;
(b) a gelatin that has a bloom number of from 50 to 130 and a weight average molecular mass of from 15,000 to 30,000 g/mol;
(c) halide ions; and
(d) an inorganic or organic acid.

2. The aqueous composition according to claim 1, consisting essentially of
(a) the copper ions;
(b) the gelatin;
(c) the halide ions;
(d) the inorganic or organic acid;
(e) optionally a sulfur containing accelerating agent;
(f) optionally a polyalkylene oxide suppressing agent; and
(g) water.

3. (canceled)

4. The aqueous composition according to claim 1, consisting essentially of
(a) the copper ions;
(b) the gelatin;
(c) chloride ions; and
(d) the inorganic or organic acid; and
(e) water.

5. (canceled)

6. (canceled)

7. The aqueous composition according to claim 1, wherein the gelatin has a bloom number of from 75 to 125.

8. (canceled)

9. The aqueous composition according to claim 1, wherein the gelatin has a weight average molecular mass of from 20,000 to 25,000 g/mol.

10. The aqueous composition according to claim 1, wherein free carboxyl groups in the gelatin are of from 60 to 130 mmol/100 g.

11. The aqueous composition according to claim 10, wherein free carboxyl groups in the gelatin are of from 90 to 130 mmol/100 g.

12. The aqueous composition according to claim 1, wherein the copper ions are present in an amount of from 20 to 60 g/l.

13. The aqueous composition according to claim 12, wherein the copper ions are present in an amount of from 30 to 50 g/l.

14. The aqueous composition according to claim 1, wherein the gelatin is present in an amount of from 3 to 50 mg/l.

15. The aqueous composition according to claim 14, wherein the gelatin is present in an amount of from 5 to 30 mg/l.

16. The aqueous composition according to claim 1, wherein the halide is present in an amount of from 20 to 120 mg/l.

17. The aqueous composition according to claim 16, wherein the halide is chloride.

18. The aqueous composition according to claim 16, wherein the halide is present in an amount of 30 to 70 mg/l.

19. The aqueous composition according to claim 1, comprising the inorganic or organic acid in a concentration of from 5 to 70 g/l.

20. The aqueous composition according to claim 19, the inorganic or organic acid is present in a concentration of from 7.5 to 40 g/l.

21. The aqueous composition according to claim 1, being devoid of any divalent sulfur-containing compounds; any polyalkylene oxide or polyalkylene glycol compounds; and/or any polyalkylene imine compounds.

22. The aqueous composition according to claim 1, which is essentially free of tin ions and nickel ions

23. (canceled)

24. The aqueous composition according to claim 1, which is essentially free of any alloying metal ions.

25. (canceled)

26. A method of using the aqueous composition according to claim 1, the method comprising using the aqueous composition for depositing nanotwinned copper on a substrate.

27. The method according to claim 26, wherein the substrate is a semiconductor substrate.

28. A process for electrodepositing copper on a substrate comprising a recessed feature comprising a conductive feature bottom and a dielectric or conductive feature side wall, the process comprising:
a) contacting the aqueous composition according to claim 1 with the substrate, and
b) applying a current to the substrate for a time sufficient to deposit nanotwinned copper on the substrate.

29. The process according to claim 28, wherein a current density of 0.5 to 4 ASD is applied.
